(19) United States
(12) Patent Application Publication
(10) Pub. No.: US 2009/0129024 A1
(43) Pub. Date: May 21, 2009

(54) INVERTED THROUGH CIRCUIT BOARD MOUNTING WITH HEAT SINK

(76) Inventors: Dennis Mahoney, Tucson, AZ (US); Daniel Alexandro Garcia, Tucson, AZ (US)

Correspondence Address: HAYES SOLOWAY P.C., 3450 E. SUNRISE DRIVE, SUITE 140, TUCSON, AZ, 85718, US

(21) Appl. No.: 11/941,023

(22) Filed: Nov. 15, 2007

(51) Int. Cl. H05K 7/20; H05K 7/10

(52) U.S. Cl. 361/709; 361/767

(57) ABSTRACT

The apparatus contains a printed circuit board in which a heat sink is mounted adjacent to one side of the printed circuit board in contact with a heat generating device mounted to the circuit board and positioned at least in part within an aperture in the circuit board.

### FIELD OF THE INVENTION

The present invention relates in general to electronic circuit boards with heat sinks. The invention has particular utility in connection with circuit board mounted power amplifiers and will be described in connection with such utility, although other utilities are contemplated including other heat generating circuit components.

### BACKGROUND

Power amplifiers are commonly used in various electronic products. Since power amplifiers generate a great amount of heat, if the heat is not dissipated efficiently, the heat may degrade the devices, diminish the overall performance of the devices and shorten the device life. Referring to FIG. 1, conventional surface mounted devices 30 have so-called “gull-wing” shaped leads. Such devices typically are formed with flat leads (i.e. leads in the plane of the device), and encapsulated in that form. The device is then placed in a “trim and fit” jig, which trims off excess lead length and bends the leads into a familiar “gull-wing” shape, that is a crooked of “z” shape with a first leg bent downwards and a second leg bent back into the horizontal at a level slightly below the bottom surface of the device. The device is then surface mounted onto the surface of a circuit board 32 with the horizontal legs of the leads 34 in contact with lands 36 or wire traces on the circuit board, bringing the device heat slug (not shown) in contact with the circuit board. However, such conventionally mounted devices have limited power dissipation. While it may be possible to increase power dissipation by incorporating a heat dissipation layer into the board, this layer adds significantly to the cost of the board.

Alternatively, as illustrated in FIG. 2, when higher power dissipation is required, a prior art practice is to flip the device over, and to mount the device 30 in an inverted position on the board, i.e. with the heat slug 38 facing away from the board, so that a heat sink 20 may be directly coupled to the heat slug 38. However, in order to mount the device in such an inverted orientation, the device leads 34 must be custom shaped, which adds significantly to costs. Also, mounting the device 30 in an inverted position on the board with a heat sink 20 mounted atop adds to the stacking height of the board which defeats the industry desire for compact boards with higher circuit densities.

### SUMMARY

The present invention provides improvements in mounting of heat generating electronic modules and heat sinks which facilitates dissipation of heat and also reduces stacking height. More particularly, in accordance with one aspect of the present invention, a circuit board is provided with an aperture so that a surface mounted power module or other heat generating device may be located at least partially within the aperture and mounted flush to the back side of the board thermally coupled to a heat sink. The power module or heat generating device may be in direct contact with the heat sink or through a direct thermal path.

In yet another aspect of the invention, there is provided a printed circuit board having a first side and a second side, and having an integrated circuit positioned at least partially within an aperture formed in the printed circuit board, and mounted to the printed circuit board by gull-wing shaped leads.

In still yet another aspect of the invention, there is provided a method of mounting a heat generating device to a circuit board which comprises the steps of providing a circuit board having a first and second side with an aperture formed through the board of size sufficient to accommodate the heat generating device; positioning the heat generating device at least partially within the aperture and mounting the heat generating device to the board; and locating a heat sink adjacent to one side of the circuit board in thermal contact with the heat generating device.

### BRIEF DESCRIPTION OF THE DRAWINGS

Yet other features and advantages of the present invention will be seen from the following detailed description, taken into conjunction with the accompanying drawings wherein like numerals depict like parts, and wherein:

FIGS. 1 and 2 are perspective views of an integrated circuit power supply mounted to a circuit board in accordance with the prior art;

FIG. 3 is a perspective view showing a power supply and heat sink mounted to a circuit board in accordance with an embodiment of the present invention; and

FIG. 4 is an enlarged view similar to FIG. 3, showing details of the invention;

### DETAILED DESCRIPTION

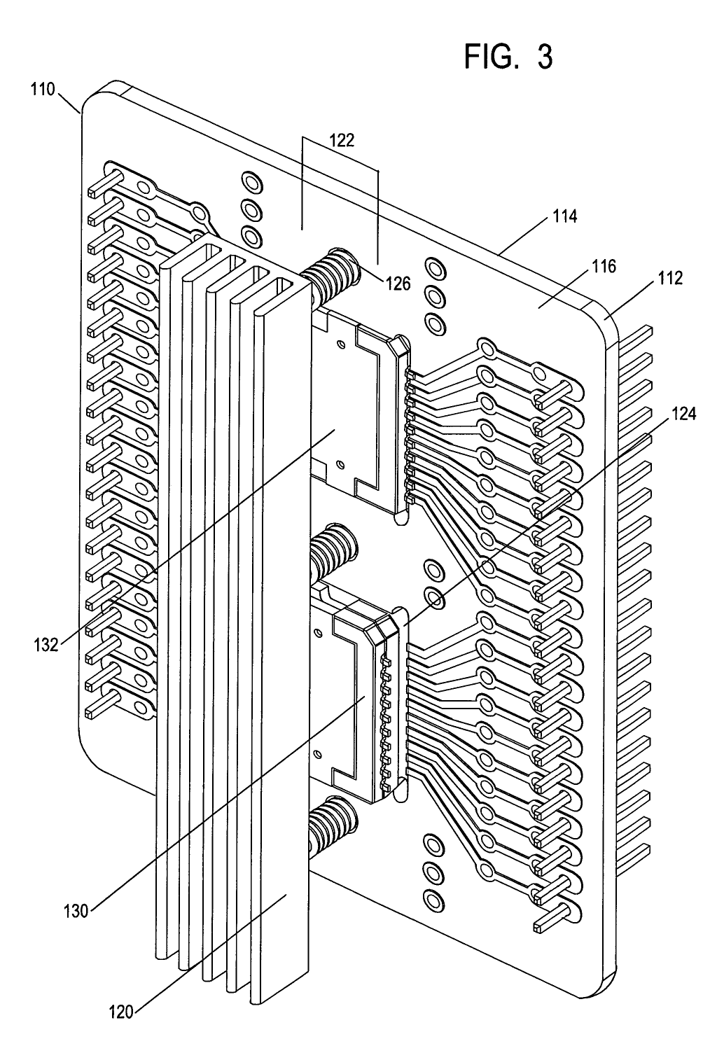

FIG. 3 is a perspective illustration of a circuit board assembly 110 having a power dissipation apparatus, in accordance with a first exemplary embodiment of the present invention. The circuit board assembly 110 includes a printed circuit board 112 having one side 114 and another side 116. A heat sink 120 is mounted on the second side 116 of the printed circuit board 112, along a middle portion 122 of the printed circuit board 112. At least one aperture 124 is formed in the printed circuit board 112 for accommodating, at least in part, a heat generating device 130 such as an integrated circuit power amplifier.

The printed circuit board 112 can be, for example, an industry standard printed circuit board or an adapter that can interface to a circuit system. The printed circuit board 112 may be constructed using conventional circuit board production methods. In an exemplary embodiment, two apertures 124 are formed in the printed circuit board 112, for accommodating two heat generating devices 130, although fewer or a greater number of apertures may be provided without deviating from the scope of the present invention. Also, for ease of illustration, FIG. 3 is illustrated partially exploded.

The heat sink 120 is fixed to the printed circuit board 112 using a plurality of fasteners 126 which may be metal fasteners including to but not limited to screws or rivets mounted through one side 114 of the printed circuit board 112 to hold the heat sink 120 to the other side 116 of the printed circuit board 112 in contact with the heat generating device 130. Alternatively, the heat sink may be adhesively attached to the board or directly to the device using a thermally conductive interface, such as a thermal grease or a conductive epoxy adhesive. Heat sink 120 preferably but not necessarily comprises a multi fin radiator to facilitate dissipation of heat.

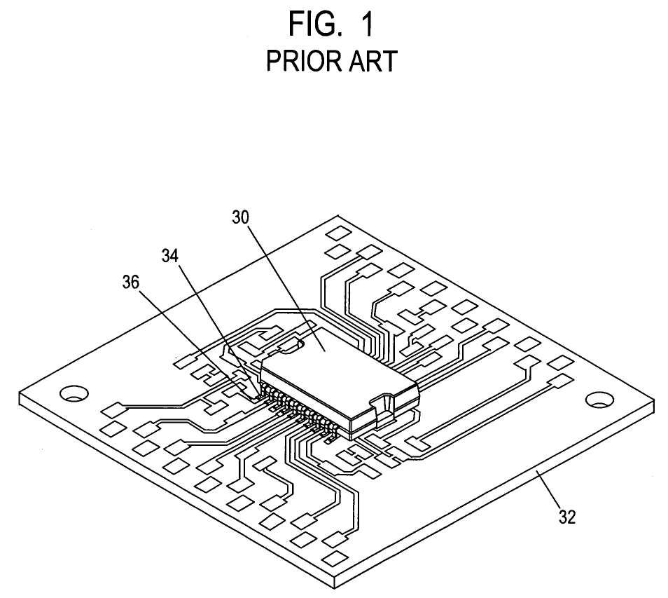

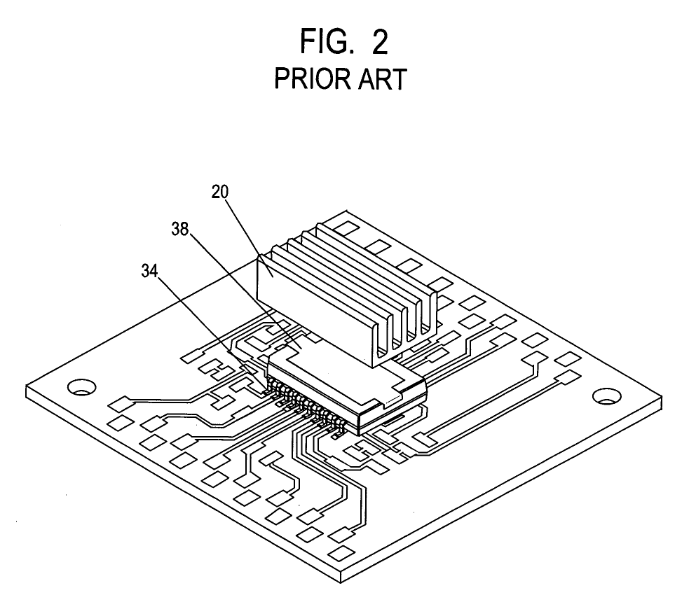

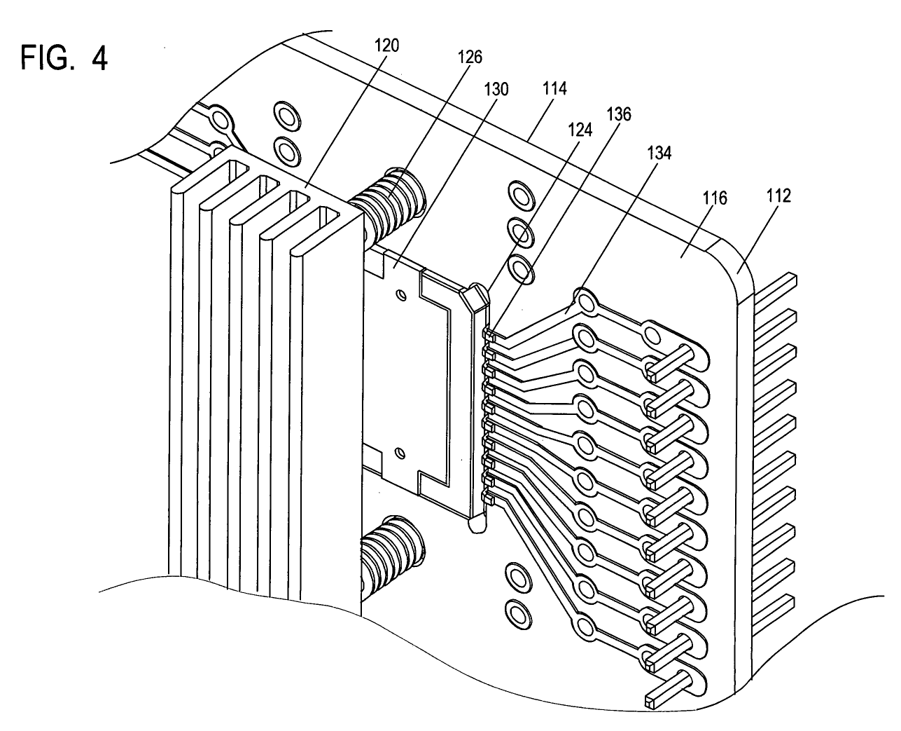

Referring also to FIG. 4, the heat generating device 130 is located at least partially within aperture 124 and soldered to the circuit board 112. However, unlike mounting to a conventional circuit board as shown in FIG. 1, the heat generating device 130 with the familiar “gull-wing” shaped leads is first positioned into the inverted orientation before mounting towards the aperture 124 and to the board, so that the device heat slug 132 is located essentially flush with the surface of the circuit board on which the lands or wire traces 134 are formed. In terms of manufacturing, the heat generating device 130 is affixed to the circuit board 112 by soldering the device leads 136 to lands or wire traces 134 on the surface of the board, and the heat sink 120 is then mounted to the board. In this way, the heat sink 120 may be in direct thermal contact with the heat generating device 130.

The present invention has several advantages over the prior art. First, mounting the heat generating device 130 in direct contact with the heat sink 120 significantly increases heat dissipation. Secondly, implementation of the invention is straight forward, and uses standard printed circuit boards that need merely to have apertures provided therein for accommodating the heat generating devices. Thirdly, mounting of the heat generating devices 130 to the board may be accomplished using conventional assembly methods such as mass soldering techniques. Fourthly, even though the heat generating devices are mounted in inverted positions to the circuit board, reshaping of the device leads is not necessary, which is very significant. Fifthly, the resulting assembly is compact and has a reduced stacking height as compared to a conventionally mounted circuit board with a heat sink. The result is increased power density per area with reduced stacking height.

The invention has other advantages. For example, the heat sink 120 also may serve to clamp the device into position in the board which in turn contributes to reliability since the clamping forces will hold the device in contact with the board even if a solder joint fails. Also, the heat sink may be used to temporarily clamp a device into position without the need to solder the leads, for example, for testing a device.

It should be noted that the above-described embodiments of the present invention, are merely possible examples of implementations, merely set forth for a clear understanding of the principles of the invention. Many variations and modifications may be made to the above-described embodiments of the invention without departing substantially from the spirit and principles of the invention. All such modifications and variations are intended to be included herein within the scope of this disclosure and the present invention and protected by the following claims.

What is claimed is:

1. An electronic device mounting arrangement, comprising:
a printed circuit board having one side and an other side;
a heat sink located adjacent to one side of the printed circuit board; and
at least one heat generating device positioned at least partially within an aperture formed in the printed circuit board and in thermal contact with the heat sink.

2. The electronic device mounting arrangement of claim 1, wherein the heat sink is mechanically attached to the printed circuit board.

3. The electronic device mounting arrangement of claim 2, wherein the heat sink is mechanically attached with metal fasteners mounted through the one side of the printed circuit board to the other side of the printed circuit board.

4. The electronic device mounting arrangement of claim 1, wherein the heat sink is adhesively attached to the printed circuit board.

5. The electronic device mounting arrangement of claim 1, wherein the heat sink is adhesively attached to the device.

6. The electronic device mounting arrangement of claim 1, wherein the heat sink comprises a multi-fin heat sink.

7. The electronic device mounting arrangement of claim 1, wherein the at least one heat generating device is mounted in an inverted orientation to the board.

8. The electronic device mounting arrangement of claim 1, wherein the heat generating device is soldered to the printed circuit board.

9. The electronic device mounting arrangement of claim 1, wherein the heat generating device is mounted to the circuit board so that an exposed surface of the heat generating device is essentially flush with the one side of the circuit board.

10. The electronic device mounting arrangement of claim 1, wherein the heat generating device is an integrated circuit.

11. The electronic device mounting arrangement of claim 1, wherein the heat generating device is a power module.

12. A method of mounting a heat generating device to a circuit board which comprises providing a circuit board having one side and an other side with an aperture formed through the board of size sufficient to accommodate the heat generating device;
positioning the heat generating device at least partially within the aperture and mounting the heat generating device to the board; and
locating a heat sink adjacent to one side of the circuit board in thermal contact with the heat generating device.

13. The method of claim 12, wherein the heat generating device is soldered to the circuit board.

14. The method of claim 12, wherein the heat sink is mounted to the circuit board by mechanical fasteners.

15. The method of claim 12, wherein the heat sink is adhesively mounted to the board.

16. The method of claim 12, wherein the heat sink is adhesively mounted to the device.

17. The method of claim 12, including the step of positioning the heat generating device so that an exposed surface of the heat generating device is essentially flush with the one side of the circuit board.

18. The method of claim 12, wherein the heat generating device is an integrated circuit.

19. The method of claim 12, wherein the heat generating device is a power module.

20. A printed circuit board assembly having a first side and a second side, and an integrated circuit positioned at least partially within an aperture formed in the printed circuit board, and mounted to the printed circuit board by gull-wing shaped leads.

21. The printed circuit board assembly of claim 20, wherein the integrated circuit is mounted in an inverted orientation to the board.

22. The circuit board assembly according to claim 20, wherein the integrated circuit is a heat generating device.

23. The printed circuit board assembly of claim 20, wherein the integrated circuit is mounted to the circuit board so that an exposed surface of the integrated circuit is essentially flush with a surface of the circuit board.
